(19) United States
(12) Patent Application Publication
(10) Pub. No.: US 2012/0186622 A1
(43) Pub. Date: Jul. 26, 2012

(54) MOLDED-IN SOLAR MODULE AND METHOD FOR MANFACTURING THE SAME

(75) Inventors: MAHENDRA SOMASARA DASSANAYAKE, BLOOMFIELD HILLS, MI (US); DONALD PAUL BILGER, LIVONIA, MI (US)

(73) Assignee: FORD GLOBAL TECHNOLOGIES, LLC, DEARBORN, MI (US)

(21) Appl. No.: 13/012,766

(22) Filed: Jan. 24, 2011

(51) Int. Cl. H01L 31/042; H01L 31/0203

(52) U.S. Cl. 136/244; 438/66; 257/E31.117

(57) ABSTRACT

A flexible solar module and manufacturing method for a portable device as an in-mold decoration is described. The solar module includes a flexible photovoltaic sheet of a predetermined shape and size, having an overmolded non-active side, mounted on the surface of a portable device. An electrical connection connected to the overmolded photovoltaic sheet terminates at any of the elements in the portable device requiring electrical power.

### BACKGROUND

The present application relates generally to solar energy generation, and more particularly to solar modules for portable devices.

At present, most portable devices, such as vehicles or portable electronics, employ batteries as power supply. Batteries however, are heavy and occupy a considerable amount of space, making them less suitable for portable devices. Further, the charge within the batteries often runs out, and generally, an electrical connection is required to recharge the batteries.

Solar cells offer a promising means for generating supplemental energy in a portable device such as a motor vehicle or portable electronics. The issues associated with installing these solar cells on the portable device, however, have delayed their adoption in new designs. The fragility of solar cells has been an additional impediment to their use. The introduction of durable semi-flexible solar cells has made it easier to package these parts, but fastening and lead dress issues still present challenges. At present, to strengthen manufactured solar cell modules, they can be laminated with a transparent plastic, which adds another step to the solar cell packaging process. Further, lamination adds only a thin layer of plastic to the solar cell and fails to provide the necessary resistance to bending or impact.

A need exists to manufacture a sturdier solar module for use in portable devices, while simplifying the manufacturing process and connectivity.

### SUMMARY

One embodiment of the present disclosure describes a flexible solar module for mounting on a portable device as an in-mold decoration. The solar module includes a flexible photovoltaic sheet of a predetermined shape and size, having an overmolded non-active side, mounted on the surface of a portable device. An electrical connection connected to the overmolded photovoltaic sheet terminates at any of the elements in the portable device requiring electrical power.

Another embodiment of the present disclosure describes a method for manufacturing a flexible solar module for mounting on a portable device as an in-mold decoration. The method includes providing a flexible photovoltaic sheet with an attached electrical connection. The photovoltaic sheet is trimmed to a predetermined shape and size and mounted on the surface of the portable device. The method further includes overmolding the non-active side of the photovoltaic sheet and also connecting the electrical connection to any of the elements in the portable device requiring electrical power.

### BRIEF DESCRIPTION OF THE DRAWINGS

The figures described below set out and illustrate a number of exemplary embodiments of the disclosure. Throughout the drawings, like reference numerals refer to identical or functionally similar elements. The drawings are illustrative in nature and are not drawn to scale.

FIG. 1 is a side view of an exemplary solar module for mounting on a portable device as an in-mold decoration.

FIG. 2 is a plan view of the solar module of FIG. 1.

FIG. 3 is the side view of an alternative embodiment of a solar module for mounting on a portable device as an in-mold decoration.

FIG. 4 depicts an exemplary method 400 for manufacturing a solar module and mounting it on a portable device as an in-mold decoration

### DETAILED DESCRIPTION

The following detailed description is made with reference to the figures. Exemplary embodiments are described to illustrate the subject matter of the disclosure, not to limit its scope, which is defined by the appended claims.

### Description of Exemplary Embodiments

The present disclosure describes embodiments of a flexible solar module for mounting on a portable device as an in-mold decoration. In-mold decoration is a process of overmolding on decorated thermoplastic film or applied with an overlay of melted thermoplastic material, sometimes providing color and texture to the substrate. The solar module includes a flexible photovoltaic sheet of a predetermined shape and size, having an injection molded (or overmolded) non-active side, mounted on the surface of a portable device. An electrical connection connected to the overmolded photovoltaic sheet terminates at any of the elements in the portable device requiring electrical power. This solution integrates a solar cell with a durable assembly that can be securely attached to the vehicle. The assembly addresses the retention problem associated with solar cell in vehicles and also enhances the durability of the solar cell.

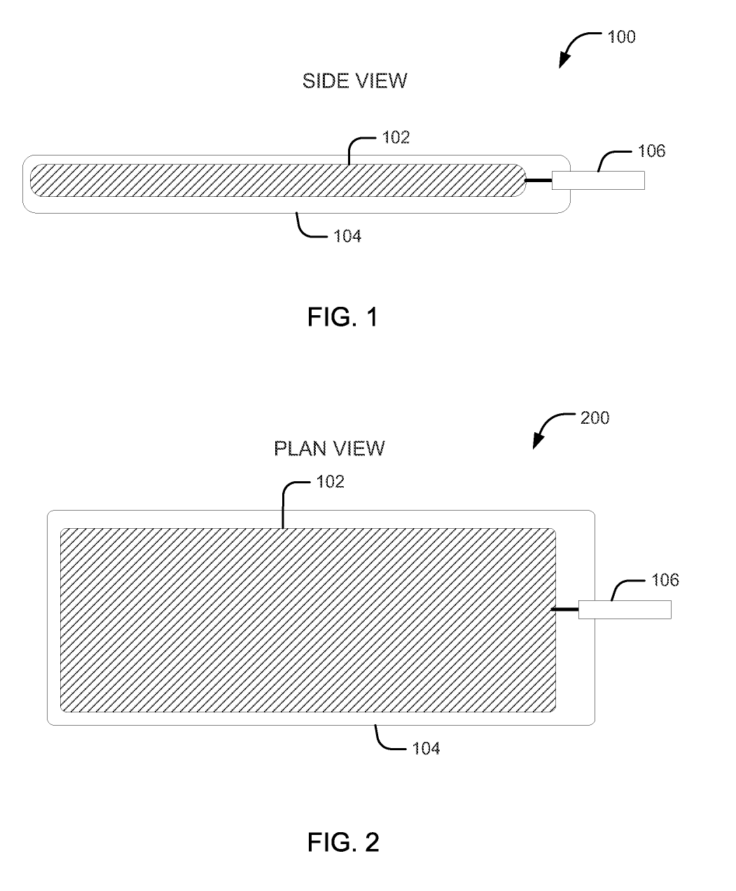

FIG. 1 depicts the side view of an exemplary solar module 100 for mounting on a portable device as an in-mold decoration. Some examples of the portable device include vehicles such as cars or trucks, and portable electronics such as cell phones.

The solar module 100 includes a flexible photovoltaic sheet 102, which may be pre-formed or pre-trimmed to a predetermined shape and size, depending on the surface on which the photovoltaic sheet 102 is to be mounted. In FIG. 1, the upper side is the active side, receiving solar energy, while the lower side is the non-active side of the photovoltaic sheet 102.

The solar module 100 may be mounted on the surface of the portable device, which may be portable electronic devices or vehicles. On vehicles, the solar module 100 can be mounted on various surfaces of a vehicle such as package trays, roof panels, upper door appliqués, the vehicle battery, exterior lighting assemblies, or instrument panels. Another application of the solar module 100 is within defense services. The solar module 100 can reduce soldier fatigue by obviating the need for carrying batteries.

Insert molding (also referred to as overmolding) is the process where a flexible film is molded on a part or substrate. The process involves the placement of a film(s) into an open mold tool cavity. The film is held in place by features of the film or the mold tool. The mold is closed and the cavity is filled with resin. The resin molds the film onto a structure. Typically, the molding process is injection molding but other molding techniques can be used.

A two-shot insert molding process may be performed on the photovoltaic sheet 102. The non-active side is overmolded with a material such as polycarbonate. The active side may also be overmolded with a transparent resin material, such as acrylic, allowing the photovoltaic sheet 102 to receive solar energy from the sun. Further, the acrylic may be scratch resistant. The overmolding layer on the active side may be glossy or textured, as desired, adding to the aesthetic appeal of the design. Further, the texture may be utilized for inhibiting specular reflection. The overmolding process strengthens the solar module 100 by providing an additional layer of protection and facilitates use in mobile devices and vehicles by minimizing damage due to wear. The overmolding layers on the active and non-active sides are collectively referred to as the overmolding layer 104.

An electrical connection 106 is connected to the overmolded photovoltaic sheet 102. The electrical connection 106 can terminate at any of the elements in the portable device requiring electrical power. For example, in a vehicle, the electrical connection 106 may connect the photovoltaic sheet 102 to any of various components such as the rear lighting systems or even the vehicle battery.

FIG. 2 illustrates the plan view of the solar module 100. Here, the electrical connection 106 is partially overmolded, however, in one embodiment, the electrical connection 106 is completely external to the overmolding layer 104. Partially or fully overmolding the electrical connection 106 prevents damage to it. Alternatively, it may be easier to mate the electrical connection 106 to the vehicle's wiring harness if the electrical connection 106 lies external to the overmolding layer 104. Here, the longitudinal axis of the electrical connection 106 is parallel to the longitudinal axis of the photovoltaic sheet 102. It will be understood by those in the art, however, that the electrical connection 106 may be aligned at any angle depending on the location of the element of the portable device where the electrical connection 106 is to be terminated.

In one embodiment of the present disclosure, the photovoltaic sheet 102 may be integrated into a skin and foam instrument panel pad to form a solar module. The photovoltaic sheet 102 may be transparent and in the form of a ribbon. The photovoltaic ribbon is provided with wire or flex circuit electrical connections and is inserted in a mold used to form skin and foam instrument panel pads. After molding and trimming, the flex circuit or leads may be terminated to their associated power electronics. The upper overmolding layer is a skin and foam instrument panel pad, which may be formed from polytetrafluoroethylene or other transparent foam like material. The lower overmolding layer may be polycarbonate, which provides color to the transparent photovoltaic ribbon. The transparent photovoltaic ribbon acts as a scattering element and can also reduce the light reflected onto the windscreen. Therefore, the solar module serves as a functional as well as styling element.

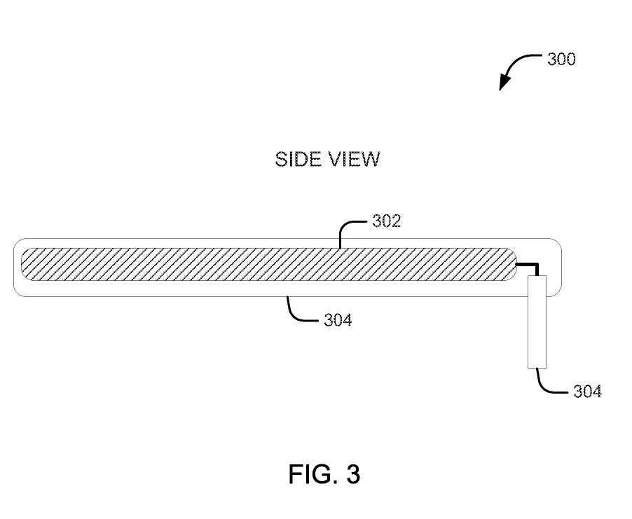

FIG. 3 shows the side view of an alternative embodiment of a solar module 300 for mounting on a portable device as an in-mold decoration. The solar module 300 includes a photovoltaic sheet 302 surrounded by an overmolding layer 304, similar to the solar module 100 of FIG. 1. An electrical connection 306, however, has its longitudinal axis perpendicular to the longitudinal axis of the photovoltaic sheet 302, which may make it easier to route the electrical connection 306 so that it is not visible to passengers. In other implementations, the electrical connection 306 may be oriented at other angles, depending on the requirement.

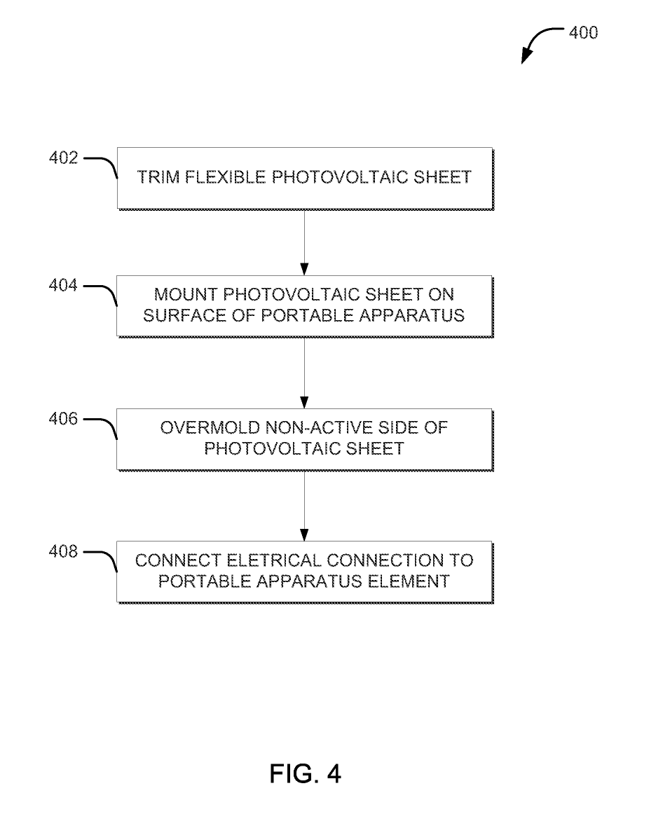

FIG. 4 depicts an exemplary method 400 for manufacturing a solar module and mounting it on a portable device as an in-mold decoration. A flexible photovoltaic sheet has an attached electrical connection. The photovoltaic sheet is pre-trimmed or pre-formed to a predetermined shape and size at step 402, based on the surface that the photovoltaic sheet is to be mounted on. Here, the electrical connection may be a polyimide flex circuit pigtail. The photovoltaic sheet is mounted on the surface of the portable device at step 404, which may be a vehicle or a mobile electronic device.

The photovoltaic sheet is overmolded at step 406. In one implementation, the photovoltaic sheet is inserted in a mold and heated bulk resin is injected under pressure to bond with the non-active side of the photovoltaic sheet. The molding tool is designed such that the wiring pigtail is not overmolded, but is left free so that it may be terminated to the power electronics at a later time using a low-insertion-force or zero-insertion-force connector. Alternatively, the wiring pigtail may be partially overmolded to provide greater strain relief at the point where the pigtail exits the overmolded assembly. Alternatively, a two shot overmolding process may be used, where the non-active side is overmolded with polycarbonate while the active side is molded with a transparent resin material such as acrylic.

Finally, at step 408, the electrical connection is connected to one or more elements requiring electrical power in the portable device, as already discussed in relation with FIG. 1. It will be understood by those skilled in the art that the order in which the steps of the method 400 have been recited may vary in other implementations. For example, the overmolding step 406 may be performed before the trimming and mounting steps.

The specification has set out a number of specific exemplary embodiments, but those skilled in the art will understand that variations in these embodiments will naturally occur in the course of embodying the subject matter of the disclosure in specific implementations and environments. It will further be understood that such variation and others as well, fall within the scope of the disclosure. Neither those possible variations nor the specific examples set above are set out to limit the scope of the disclosure. Rather, the scope of claimed invention is defined solely by the claims set out below.

What is claimed is:

1. A flexible solar module for mounting on a portable device, the solar module comprising:
a flexible photovoltaic sheet of a predetermined shape and size, having an overmolded non-active side, mounted on the surface of a portable device; and
an electrical connection connected to the overmolded photovoltaic sheet, wherein the electrical connection terminates at any of the elements in the portable device requiring electrical power.

2. The solar module of claim 1, wherein the electrical connection is a flex circuit pigtail.

3. The solar module of claim 1, wherein the electrical connection is partially overmolded.

4. The solar module of claim 1, wherein the active side of the photovoltaic sheet is also overmolded.

5. The solar module of claim 4, wherein the overmolding on the active side is done with a transparent resin.

6. The solar module of claim 4, wherein the transparent resin is acrylic.

7. The solar module of claim 4, wherein the overmolding results in a textured surface.

8. The solar module of claim 1, wherein the overmolding on the non-active side is done with polycarbonate.

9. The solar module of claim 1, wherein the portable device is a vehicle, and the surface is one or more of:
a package tray;
a decklid-mounted spoiler;
a roof panel;
upper door appliqués;
a vehicle battery;
an exterior lighting assembly; or
an instrument panel.

10. A method for manufacturing a flexible solar module for mounting on a portable device, the method comprising:
providing a flexible photovoltaic sheet with an attached electrical connection;
trimming the photovoltaic sheet to a predetermined shape and size;
mounting the photovoltaic sheet on the surface of the portable device;
overmolding the non-active side of the photovoltaic sheet; and
connecting the electrical connection to any of the elements in the portable device requiring electrical power.

11. The method of claim 10, wherein the electrical connection is a flex circuit pigtail.

12. The method of claim 10 further comprising partially overmolding the electrical connection.

13. The method of claim 10 further comprising overmolding the active side of the photovoltaic sheet.

14. The method of claim 13, wherein the overmolding on the active side is done with a transparent resin.

15. The method of claim 13, wherein the transparent resin is acrylic.

16. The method of claim 13, wherein the overmolding results in a textured surface.

17. The method of claim 10, wherein the overmolding on the non-active side is done with polycarbonate.

18. The method of claim 10, wherein the potable device is a vehicle, and the surface is one or more of:
a package tray;
a decklid-mounted spoiler;
a roof panel;
upper door appliqués;
a vehicle battery;
an exterior lighting assembly; or
an instrument panel.

19. A flexible solar module for mounting on vehicles, the solar module comprising:
a flexible photovoltaic sheet of a predetermined shape and size, having an overmolded non-active side, mounted on a vehicle surface;
an active side of the photovoltaic sheet covered by a skin and foam instrument panel pad; and
an electrical connection connected to the overmolded photovoltaic sheet, wherein the electrical connection terminates at any of the vehicle power electronics.
